(19) United States
(12) Patent Application Publication
(10) Pub. No.: US 2025/0147156 A1
(43) Pub. Date: May 8, 2025

(54) SAFETY PROTECTION CIRCUIT AND DRIVE DETECTION METHOD FOR LIDAR AND DRIVER CIRCUIT THEREOF

(71) Applicant: HESAI TECHNOLOGY CO., LTD., Shanghai (CN)

(72) Inventors: Chengguang LI, Shanghai (CN); Biao WANG, Shanghai (CN); Xin ZHAO, Shanghai (CN); Shaoqing XIANG, Shanghai (CN)

(21) Appl. No.: 19/018,785

(22) Filed: Jan. 13, 2025

Related U.S. Application Data
(63) Continuation of application No. PCT/CN2023/080433, filed on Mar. 9, 2023.

(30) Foreign Application Priority Data
Jul. 15, 2022 (CN) 202210833754.X

(51) Int. Cl. G01S 7/484; G01R 19/165; H02H 3/24

(52) U.S. Cl. CPC G01S 7/484; G01R 19/16576; H02H 3/24

(57) ABSTRACT

This disclosure provides a safety protection circuit and a drive detection method for a LiDAR and a driver circuit thereof. The LiDAR includes a light-emitter apparatus, and the driver circuit provides a drive voltage to drive the light-emitter apparatus to emit light. One end of the light-emitter apparatus receives the drive voltage, and the other end of the light-emitter apparatus is coupled to a drive switch. The safety protection circuit includes: a voltage detector unit configured to detect a voltage value of the drive voltage; and a safety controller unit configured to control the driver circuit to stop providing the drive voltage when a voltage value of the drive voltage is lower than a threshold voltage, wherein the threshold voltage represents a voltage value of the drive voltage when the drive switch fails.

### CROSS-REFERENCE TO RELATED APPLICATIONS

This application is a continuation application of and claims benefit of copending International Patent Application No. PCT/CN2023/080433, filed on Mar. 9, 2023, which claims priority to Chinese Patent Application No. 202210833754.X, filed on Jul. 15, 2022, the content of which is incorporated herein by reference in its entirety.

### TECHNICAL FIELD

This disclosure relates to the field of a LiDAR and, in particular, to a safety protection circuit and a drive detection method for a LiDAR and a driver circuit thereof.

### BACKGROUND

Related technologies for controlling a LiDAR (“Light Detection And Ranging”) to emit light pulses through a drive switch are already very mature. The drive switch, such as gallium nitride (“GaN”) field-effect transistor, has a failure rate of around 1F1T (one fault per billion hours). The drive switch has been widely used in industry due to its high reliability and high performance.

As shown in FIG. 1, in a field of the LiDAR, to reduce the number of driver circuit devices at an emitting end of laser light and thus reduce a chip area, light-emitter apparatus is generally connected to a circuit by using a manner of sharing a same pin of the light-emitter apparatus, for example, “sharing a common cathode”. Light-emitting duration and light-emitting time sequence of the light-emitter apparatus are controlled through gating switches T1-T4 and the drive switches. Light-emitter apparatuses L1-L4 are grounded via a drive switch G1. Light-emitter apparatuses L5-L8 are grounded via a drive switch G2. By ensuring that light-emitting time (i.e., light-emitting pulse width) of each light-emitter apparatus of an array of light-emitter apparatuses is maintained at around 10 ns, it can effectively avoid a problem of human eye safety.

However, the drive switches are widely used in the LiDAR. Once a certain drive switch fails, for example, a drive switch is broken down and continues to conduct, it can cause a certain light-emitter apparatus to emit light continuously, resulting in an accident of the human eye safety.

### SUMMARY

A technical problem solved by this disclosure is to promptly stop a light-emitter apparatus from emitting light in the case that a driver circuit fails, to reduce a human eye safety risk caused by continuous light emission of a LiDAR.

To solve the above technical problem, in a first aspect, embodiments of this disclosure provide a safety protection circuit for a driver circuit of a LiDAR, wherein the LiDAR includes a light-emitter apparatus, the driver circuit provides a drive voltage to drive the light-emitter apparatus to emit light, one end of the light-emitter apparatus receives the drive voltage, and the other end of the light-emitter apparatus is coupled to a drive switch; and the safety protection circuit includes: a voltage detector unit configured to detect a voltage value of the drive voltage; and a safety controller unit configured to control the driver circuit to stop providing the drive voltage when a voltage value of the drive voltage is lower than a threshold voltage, the threshold voltage represents a voltage value of the drive voltage when the drive switch fails.

Optionally, when the light-emitter apparatus emits the light normally, the drive voltage has a maximum voltage value and a minimum voltage value during a voltage repetition period, and the threshold voltage is less than the minimum voltage value.

Optionally, a difference value between the maximum voltage value and the minimum voltage value is a first voltage variation, the threshold voltage is a difference value between the minimum voltage value and a safety voltage variation, and the safety voltage variation is a product of the first voltage variation and a preset ratio.

Optionally, the threshold voltage is less than the minimum voltage value and greater than a safety allowable voltage value, and the safety allowable voltage value is a voltage value of the drive voltage when light-emitting duration of the light-emitter apparatus reaches a safety light-emitting time threshold.

Optionally, the threshold voltage is an intermediate value between the minimum voltage value and the safety allowable voltage value.

Optionally, the driver circuit includes a charger unit and an energy storage unit, wherein the charger unit is configured to charge the energy storage unit, and the energy storage unit provides the drive voltage; and when the voltage value of the drive voltage is lower than the threshold voltage, the safety controller unit controls the charger unit to stop charging the energy storage unit and controls the energy storage unit to discharge.

Optionally, the voltage detector unit includes: a comparison subunit configured to output a first voltage based on a comparison result between the drive voltage and the threshold voltage, wherein the first voltage represents whether the drive voltage is abnormal.

Optionally, the comparison subunit includes: a first comparator, wherein a positive input end of the first comparator is connected to the threshold voltage, a negative input end of the first comparator is connected to the drive voltage, and an output end of the first comparator outputs the first voltage.

Optionally, the voltage detector unit includes: a clamp subunit, wherein an input end of the clamp subunit is connected to the drive voltage, and the clamp subunit is configured to clamp the drive voltage within a preset voltage range.

Optionally, the voltage detector unit includes: a first voltage divider subunit, wherein an input end of the first voltage divider subunit is coupled to a power supply, an output end of the first voltage divider subunit is coupled to a negative input end of the first comparator, and the first voltage divider subunit is configured to output an initial drive voltage, wherein the initial drive voltage is greater than the threshold voltage.

Optionally, the other end of N light-emitter apparatuses is coupled to a same drive switch, the number of the drive switches is M, the number of the light-emitter apparatuses of the LiDAR is N×M, and N and M are positive integers greater than 1; and the voltage detector unit is configured to detect a voltage value of the drive voltage driving the N light-emitter apparatuses.

Optionally, each light-emitter apparatus is connected to a power supply via a switch device, a first end of the switch device is coupled to the power supply, a second end of the switch device is coupled to one end of the light-emitter apparatus, and each input end of the voltage detector unit is coupled to a second end of the switch device, respectively.

Optionally, the safety controller unit includes: a discharger subunit configured to discharge a energy storage unit in the driver circuit when the voltage value of the drive voltage is lower than the threshold voltage.

Optionally, a control end of the discharger subunit is coupled to an output end of the voltage detector unit, a first end of the discharger subunit is coupled to the energy storage unit, and a second end of the discharger subunit is grounded.

Optionally, the safety controller unit includes: a controller, wherein an input end of the controller is coupled to an output end of the voltage detector unit, and an output end of the controller is coupled to an input end of the discharger subunit.

Optionally, a control end of the discharger subunit is coupled to the output end of the controller, a first end of the discharger subunit is coupled to the energy storage unit, and a second end of the discharger subunit is grounded.

Optionally, the controller controls to stop charging the energy storage unit in the driver circuit when the voltage value of the drive voltage is lower than the threshold voltage.

Optionally, the discharger subunit includes: a first load; and a first switch configured to conduct when the voltage value of the drive voltage is lower than the threshold voltage, allowing the energy storage unit to discharge via the first load.

Optionally, the safety controller unit includes: a gating subunit configured to output a first control signal when the voltage value of the drive voltage is lower than the threshold voltage, wherein the first control signal is configured to control to stop charging the energy storage unit in the driver circuit; and the gating subunit configured to output a second control signal when the voltage value of the drive voltage is higher than the threshold voltage, wherein the second control signal is configured to control to charge the energy storage unit in the driver circuit.

Optionally, an input end of the gating subunit is coupled to an output end of the voltage detector unit.

Optionally, the safety controller unit includes a controller, an input end of the controller is coupled to the output end of the voltage detector unit, and an input end of the gating subunit is coupled to an output end of the controller.

Optionally, when the voltage value of the drive voltage is lower than the threshold voltage, the controller outputs a third control signal to the input end of the gating subunit; and when the voltage value of the drive voltage is higher than the threshold voltage, the controller outputs a fourth control signal to the input end of the gating subunit.

In a second aspect, this disclosure provides a drive detection method for a LiDAR, wherein the LiDAR includes a light-emitter apparatus, a driver circuit provides a drive voltage to drive the light-emitter apparatus, and one end of the light-emitter apparatus receives the drive voltage, and the other end of the light-emitter apparatus is coupled to a drive switch; and the drive detection method includes: detecting a voltage value of the drive voltage; and when a voltage value of the drive voltage is lower than a threshold voltage, controlling the driver circuit to stop providing the drive voltage, wherein the threshold voltage represents a voltage value of the drive voltage when the drive switch fails.

Optionally, the driver circuit includes a charger unit and an energy storage unit, wherein the charger unit is configured to charge the energy storage unit, and the energy storage unit provides the drive voltage; and the controlling the driver circuit to stop providing the drive voltage includes: controlling the charger unit to stop charging the energy storage unit and controlling the energy storage unit to discharge.

In a third aspect, this disclosure provides a LiDAR, wherein the LiDAR includes a light-emitter apparatus, and the LiDAR further includes the safety protection circuit.

Compared with the prior art, technical solutions of the embodiments of this disclosure achieve the following beneficial effects.

In the technical solutions of this disclosure, the safety protection circuit is provided with the voltage detector unit and the safety controller unit. The voltage detector unit is used for detecting the voltage value of the drive voltage, and the safety controller unit is used for controlling the driver circuit to stop providing the drive voltage when the voltage value of the drive voltage is lower than the threshold voltage. Due to a continuous decrease in the drive voltage driving the light-emitter apparatus to emit the light when the drive switch fails, the embodiments of this disclosure determine whether the drive switch has failed by detecting a relationship between the voltage value of the drive voltage and the threshold voltage. In the case that the drive switch fails, the driver circuit is controlled to stop providing the drive voltage to control the light-emitter apparatus to stop emitting the light, thereby reducing a possibility of an accident of human eye safety caused by a failure of the drive switch.

Furthermore, each high-voltage bus supplies power to multiple light-emitter apparatuses coupled to the high-voltage bus. And the driver circuit controls the light-emitting duration and the light-emitting time sequence of the light-emitter apparatuses through gating switches and drive switches. The safety controller unit in this disclosure includes the discharger subunit which can discharge the energy storage unit in the driver circuit when the voltage value of the drive voltage is lower than the threshold voltage. In the embodiments of this disclosure, in the case that the drive switch fails, the light-emitter apparatus can be quickly controlled to stop emitting the light by discharging the energy storage unit in the driver circuit through the discharger subunit, further ensuring safety of light emission of the LiDAR.

### BRIEF DESCRIPTION OF THE DRAWINGS

FIG. 1 shows a schematic structural diagram of a driver circuit for a laser in the existing technology.

FIG. 2 shows a control time sequence diagram of a driver circuit in the existing technology.

FIG. 3 shows a schematic structural diagram of a safety protection circuit, provided in embodiments of this disclosure.

FIG. 4 and FIG. 5 show schematic diagrams of threshold voltage, provided in embodiments of this disclosure.

FIG. 6 shows a schematic diagram of an energy storage unit in a driver circuit, provided in embodiments of this disclosure.

FIG. 7 shows a schematic structural diagram of a voltage detector unit, provided in embodiments of this disclosure.

FIG. 8 shows a schematic structural diagram of a discharger subunit, provided in embodiments of this disclosure.

FIG. 9 shows a specific schematic structural diagram of a safety protection circuit, provided in embodiments of this disclosure.

FIG. 10 shows a specific schematic structural diagram of a safety protection circuit, provided in embodiments of this disclosure.

FIG. 11 shows a specific schematic structural diagram of another safety protection circuit, provided in embodiments of this disclosure.

FIG. 12 shows a specific schematic structural diagram of yet another safety protection circuit, provided in embodiments of this disclosure.

FIG. 13 shows a specific schematic structural diagram of still yet another safety protection circuit, provided in embodiments of this disclosure.

FIG. 14 shows a specific schematic structural diagram of still yet another safety protection circuit, provided in embodiments of this disclosure.

FIG. 15 shows a voltage time sequence diagram, provided in embodiments of this disclosure.

FIG. 16 shows a flowchart of a drive detection method for a LiDAR, provided in embodiments of this disclosure.

### DETAILED DESCRIPTION

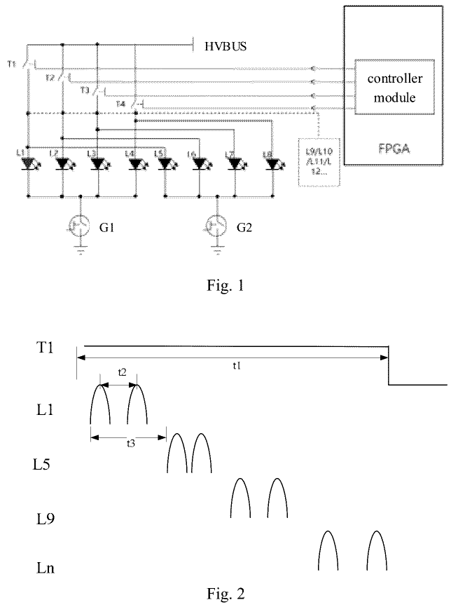

With reference to FIG. 1 and FIG. 2, a high-voltage bus (“HVBUS”) is used for providing a stable voltage source. After a field programmable gate array (“FPGA”) controls a switch T1 to close, drive switches are closed in sequence, and light-emitter apparatuses L1, L5 . . . , Ln (n=9 . . . 125) connected to the switch T1 are conducted in sequence. Closing time of each drive switch is approximately 10 nanoseconds (“ns”), that is to say, each light-emitting pulse width of light-emitter apparatus is 10 ns. And to achieve optical pulse encoding, during closing time t1 of the switch T1, lasers L1, L5 . . . , Ln need to emit at least two pulses. And the lasers L1, L5 . . . , Ln emit light in a time-division manner based on light-emitting time sequence. Pulse interval time t2 is random encoding time, and a time interval (i.e., a light-emitting period of each laser) between the lasers L1, L5 . . . , Ln is t3. In this way, the closing time t1 of the switch T1 needs to be maintained at a microsecond level.

As said in Background, drive switches are widely used in a LiDAR. Once a certain drive switch fails, for example, a drive switch is broken down and continues to conduct, which can cause a certain light-emitter apparatus to emit the light continuously, resulting in an accident of human eye safety.

For example, in FIG. 1, after the switch T1 is closed, the drive switch G1 continues to conduct due to breakdown, and a light-emitter apparatus L1 emits the light. Normally, the light-emitter apparatus L1 can stop emitting the light after emitting the light for 10 ns. However, when the drive switch G1 fails and continues to conduct, the light-emitter apparatus L1 can continue to emit the light until the switch T1 is opened. Duration t1 from closing to opening of the switch T1 is in a microsecond range. If the light-emitter apparatus continues to emit the light for more than tens of nanoseconds, it may cause the accident of the human eye safety. At this time, if there happens to be someone nearby looking directly into the light-emitter apparatus L1, it may cause permanent damage to human cornea.

In technical solutions of this disclosure, a safety protection circuit is provided with a voltage detector unit and a safety controller unit. The voltage detector unit is used for detecting a voltage value of drive voltage, and the safety controller unit is used for controlling a driver circuit to stop providing the drive voltage when the voltage value of the drive voltage is lower than a threshold voltage. When a drive switch fails, the drive voltage for driving a light-emitter apparatus to emit the light continues to decrease. Therefore, embodiments of this disclosure determine whether the drive switch fails by detecting a relationship between the voltage value of the drive voltage and the threshold voltage. In the case that the drive switch fails, the driver circuit is controlled to stop providing the drive voltage to control the light-emitter apparatus to stop emitting the light, thereby reducing a possibility of an accident of human eye safety caused by a failure of the drive switch.

Furthermore, the safety controller unit includes a discharger subunit used for discharging an energy storage unit in the driver circuit when the voltage value of the drive voltage is lower than the threshold voltage. In the embodiments of this disclosure, in the case that the drive switch fails, the energy storage unit in the driver circuit is discharged through the discharger subunit. Remaining electric charge is released timely. The light-emitter apparatus is quickly controlled to stop emitting the light, further ensuring safety of light emission of the LiDAR.

To make the above purposes, features and advantages of this disclosure more obvious and readily understood, specific embodiments of this disclosure are described below in detail with reference to drawings.

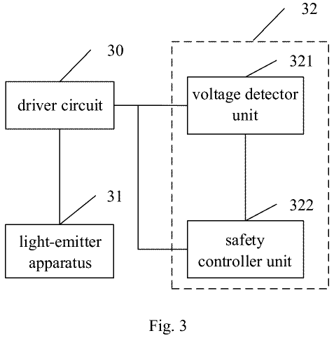

FIG. 3 shows a schematic structural diagram of a safety protection circuit, provided in embodiments of this disclosure. A safety protection circuit 32 in the embodiments of this disclosure is used in the LiDAR to ensure safe light emission of the LiDAR.

The LiDAR includes a driver circuit 30 and a light-emitter apparatus 31. The light-emitter apparatus 31 can emit the light. The driver circuit 30 can provide a drive voltage to drive the light-emitter apparatus 31 to emit the light. The light-emitter apparatus 31 can specifically be a laser, for example, a vertical-cavity surface-emitting laser (“VCSEL”) or a light-emitter apparatus of any other implementable type. In practical application, the number of light-emitter apparatuses 31 can be multiple, and the embodiments of this disclosure are not limited thereto.

The driver circuit 30 includes a drive switch, such as GaN. The light-emitter apparatus 31 is grounded through the drive switch. When the drive switch fails, it can cause the light-emitter apparatus 31 to continue emitting the light.

In this embodiment, the safety protection circuit 32 can include a voltage detector unit 321 and a safety controller unit 322. The voltage detector unit 321 is used for detecting a voltage value of the drive voltage, and the safety controller unit 322 is used for controlling the driver circuit 30 to stop providing the drive voltage when the voltage value of the drive voltage is lower than a threshold voltage. The threshold voltage represents the voltage value of the drive voltage when the drive switch fails. In other words, the voltage value of the drive voltage is lower than the threshold voltage represents that the drive switch fails. The threshold voltage can be determined in advance based on the drive voltage when the drive switch fails, which is not limited in this disclosure.

When the drive switch fails, the drive voltage for driving the light-emitter apparatus to emit the light continues to decrease. Therefore, the embodiments of this disclosure determine whether the drive switch fails by detecting a relationship between the voltage value of the drive voltage and the threshold voltage. In the case that the drive switch fails, the driver circuit is controlled to stop providing the drive voltage to control the light-emitter apparatus to stop emitting the light, thereby reducing a possibility of an accident of human eye safety caused by a failure of the drive switch.

A specific configuration of the threshold voltage can refer to the following aspects.

In a first aspect, when the light-emitter apparatus 31 emits the light normally, the drive voltage has a maximum voltage value and a minimum voltage value during a voltage repetition period, and the threshold voltage is less than the minimum voltage value.

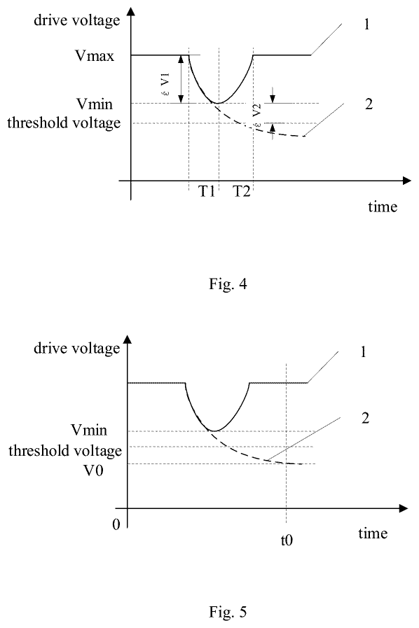

With reference to FIG. 4 for details, the light-emitter apparatus 31 emits the light normally when the drive switch does not fail, and a variation pattern of the drive voltage is shown as a curve 1. The voltage repetition period includes a time period T1 and a time period T2. T1 represents light-emitting time of the light-emitter apparatus 31. During the time period T1 the light-emitter apparatus 31 emits the light, and the drive voltage drops or changes by a first voltage variation ΔV1. T2 represents voltage recovery time after the drive voltage drops. Specifically, a voltage stabilized source or a low dropout regulator (“LDO”) can be used to change voltage and achieve voltage recovery. During the voltage repetition period, the maximum voltage value of the drive voltage is Vmax and the minimum voltage value of the drive voltage is Vmin. When the light-emitter apparatus emits a laser pulse each time, the drive voltage changes between the maximum voltage value Vmax and the minimum voltage value Vmin. When the drive switch fails and continues to conduct, the light-emitter apparatus 31 emits the light continuously, and a variation pattern of the drive voltage is shown as a curve 2. In this case, the voltage value of the drive voltage drops continuously.

In the embodiments of this disclosure, the threshold voltage is set to be less than the minimum voltage value Vmin. Once the voltage detector unit 321 detects that the drive voltage is lower than the threshold voltage, it represents that the drive voltage deviates from the curve 1 and drops continuously, and it can be determined that the drive switch fails.

It should be noted that T1 in FIG. 4 is time when the light-emitter apparatus 31 emits single pulse laser light. When the light-emitter apparatus 31 emits encoded multi pulse laser light, there can be multiple voltage drops during T1.

In a second aspect, a difference value between the maximum voltage Vmax and the minimum voltage Vmin is a first voltage variation ΔV1. The threshold voltage is a difference value between the minimum voltage Vmin and a safety voltage variation ΔV2. The safety voltage variation ΔV2 is a product of the first voltage variation ΔV1 and a preset ratio.

With reference to FIG. 4, in a specific example, the preset ratio can be 20%, that is, the safety voltage variation ΔV2 is 20% of the first voltage variation ΔV1.

In the embodiments of this disclosure, a safety margin that is, the safety voltage variation ΔV2, is set between the threshold voltage and the minimum voltage value Vmin, which can avoid false detection of the drive voltage when noise such as burrs occurs, thereby avoiding an accidental triggering of a human eye safety protection mechanism and ensuring a normal operation of the LiDAR.

In a third aspect, the threshold voltage is less than the minimum voltage value and greater than a safety allowable voltage value. The safety allowable voltage value is the voltage value of the drive voltage when light-emitting duration of the light-emitter apparatus 31 reaches a safety light-emitting time threshold.

With reference to FIG. 5 together, the safety light-emitting time threshold t0 can be pre-determined human eye safety light-emitting time of the LiDAR, that is to say, continuous light-emitting time of the LiDAR within the safety light-emitting time threshold is safe for human eye. The safety light-emitting time threshold t0 can specifically be several tens of nanoseconds. The safety allowable voltage value V0 refers to the voltage of the curve 2 at the safety light-emitting time threshold t0. The threshold voltage can be selected within a voltage range defined by the minimum voltage value Vmin and the safety allowable voltage value V0, that is to say, the threshold voltage can be any voltage within this voltage range.

Furthermore, the threshold voltage is an intermediate value between the minimum voltage value and the safety allowable voltage value. In this embodiment, the threshold voltage is ½ (Vmin+V0).

In a non-limiting embodiment of this disclosure, the safety controller unit 322 controls a charger unit to stop charging a energy storage unit and controls the energy storage unit to discharge when the voltage value of the drive voltage is lower than the threshold voltage.

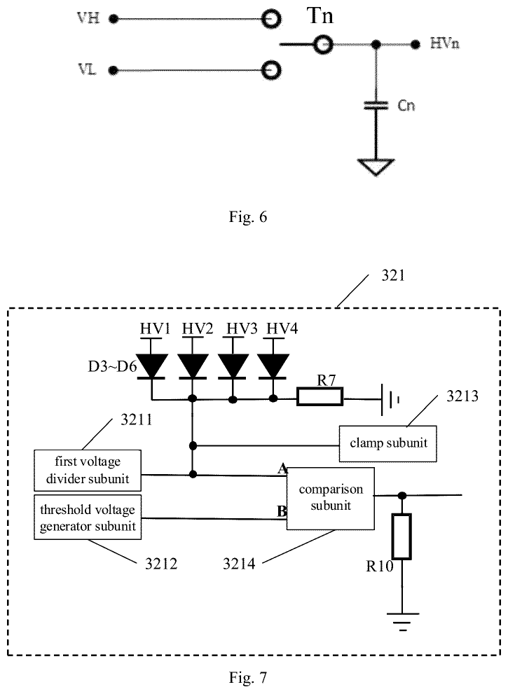

In this embodiment, the driver circuit includes the charger unit and the energy storage unit. The charger unit is used for charging the energy storage unit, and the energy storage unit provides the drive voltage. With reference to FIG. 6 for details, the energy storage unit includes a capacitor Cn. The charger unit includes power supplies VH and VL, and a switch Tn. When the charger unit charges the capacitor Cn, the capacitor Cn is connected to a power supply VH via the switch Tn. When the charger unit stops charging the capacitor Cn, the capacitor Cn is connected to a power supply VL via the switch Tn, that is, the capacitor Cn is grounded via the switch Tn.

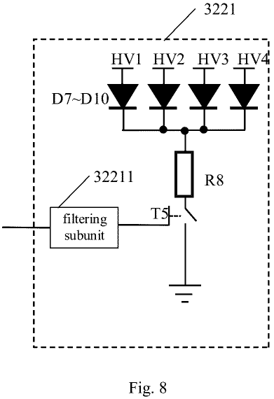

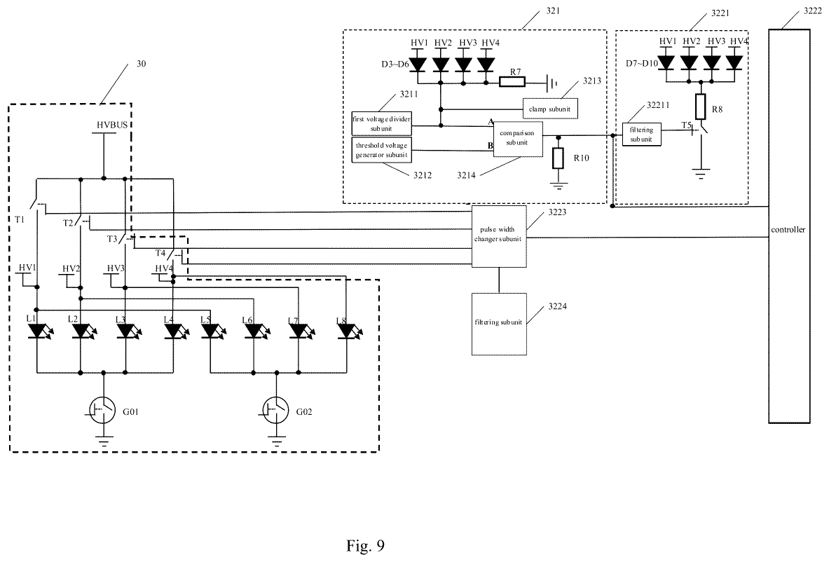

With reference to FIG. 7 together, in the embodiments of this disclosure, each of drive voltage HV1-HV4 is connected to an energy storage unit, that is, each drive voltage is connected to a capacitor Cn.

In the embodiments of this disclosure, in the case that the drive switch fails, the light-emitter apparatus can be quickly controlled to stop emitting the light by discharging the energy storage unit in the driver circuit through the discharger subunit, further ensuring the safety of the light emission of the LiDAR.

In the following, a detailed illustration is made combined with a specific structure of the safety protection circuit. The drive voltage referred to in the embodiments of this disclosure can be voltage provided to an anode of the light-emitter apparatus, that is, voltage HV shown in FIG. 6.

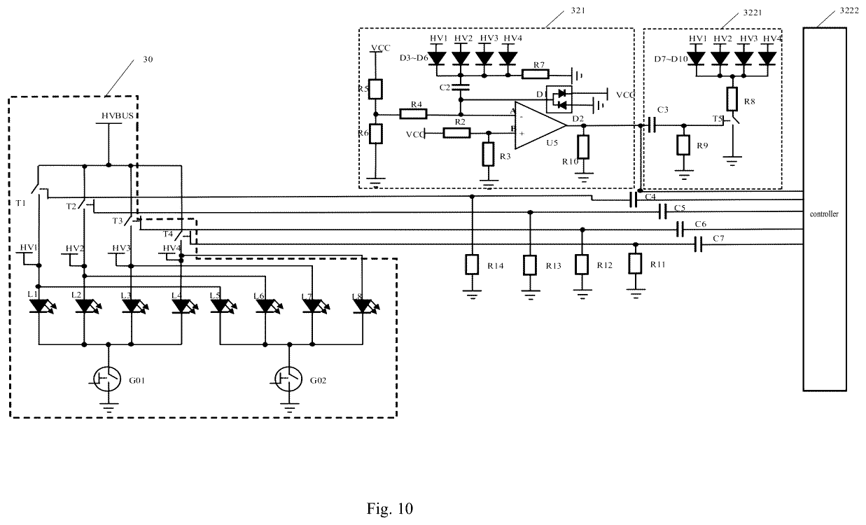

In a non-limiting embodiment of this disclosure, with reference to FIG. 7 and FIG. 9, the voltage detector unit 321 includes a comparison subunit 3214. The comparison subunit 3214 is used for outputting a first voltage based on a comparison result between the drive voltage and the threshold voltage. The first voltage represents whether the drive voltage is abnormal.

The comparison subunit 3214 can be a first comparator U5. A first input end of the first comparator U5 is connected to voltage UA, and a second input end of the first comparator U5 is connected to voltage UB. The voltage UA is the drive voltage, and the voltage UB is the threshold voltage.

In this embodiment, when the voltage UA is higher than the voltage UB, the first comparator U5 outputs a low level. When the voltage UA is lower than the voltage UB, the first comparator U5 outputs a high level.

Those skilled in the art should understand that it can also be set that the first comparator U5 outputs the low level when the voltage UA is lower than the voltage UB, and outputs the high level when the voltage UA is higher than the voltage UB, which is not limited in this disclosure.

In specific implementation, the voltage detector unit 321 includes a first voltage divider subunit 3211. The first voltage divider subunit 3211 is used for generating a initial drive voltage. The first voltage divider subunit 3211 includes a resistor R4, a resistor R5, and a resistor R6. One end of the resistor R4 is coupled to the first input end of the first comparator U5, and the other end of the resistor R4 is coupled to one end of the resistor R5. The other end of the resistor R5 is coupled to a power supply VCC. One end of the resistor R5 is coupled to one end of the resistor R6. The other end of the resistor R6 is grounded. An initial value of the voltage UA (i.e., the initial drive voltage) is determined by dividing the power supply VCC through the resistor R4, the resistor R5, and the resistor R6. The initial value of UA is a constant voltage value to ensure that a voltage value of UA is higher than a voltage value of UB.

In specific implementation, threshold voltage UB can be generated through a threshold voltage generator subunit 3212. The voltage generator subunit 3212 includes a resistor R2 and a resistor R3. The threshold voltage is obtained by dividing the power supply VCC through the resistor R2 and the resistor R3. A specific determination method of the threshold voltage can refer to the previous embodiments, which is not repeated herein.

Furthermore, the voltage detector unit 321 further includes a clamp subunit 3213. An input end of the clamp subunit 3213 is connected to the drive voltage. The clamp subunit 3213 is used for clamping the drive voltage UA within a preset voltage range. The clamp subunit 3213 can ensure that the first comparator U5 is not damaged due to high voltage during a drive voltage recovery process (i.e., voltage rising process), and can also avoid occurrence of the noise such as the burrs that can accidentally trigger a human eye safety protection mechanism.

With reference to FIG. 9, the clamp subunit 3213 includes two diodes D1 and D2 connected in series, and a capacitor C2. A cathode of the diode D1 is connected to the power supply VCC. An anode of the diode D1 is coupled to a cathode of the diode D2. An anode of the diode D2 is grounded. One end of the capacitor C2 is coupled to the anode of the diode D1 and the cathode of the diode D2 connected in series. The other end of the capacitor C2 is connected to the drive voltage. Specifically, the capacitor C2 can isolate direct current and conduct alternating current. When one of diodes D3-D6 conducts and the drive voltage connected to this diode increases, the voltage UA correspondingly increases. At this time, the voltage UA is greater than the voltage UB, and the first comparator U5 outputs the low level. When the drive voltage drops, the voltage UA correspondingly drops. If there is significant crosstalk that causes the voltage UA to drop, false triggering can occur, that is, the voltage UA is lower than the voltage UB. The voltage detector unit 321 detects that the drive voltage is abnormal. To avoid the false triggering, the voltage UA is clamped within a certain range, such as a difference value between the voltage value of the power supply VCC and conduction voltage of the diode.

Correspondingly, the safety controller unit 322 can be a controller 3222, such as an FPGA. When the voltage UA is lower than the voltage UB, it represents that the drive switch fails. At this time, the first comparator U5 outputs the high level to the controller 3222, and the controller 3222 controls the driver circuit to stop providing the drive voltage.

In a specific embodiment, FIG. 9 shows a specific structure of a safety protection circuit. The LiDAR in FIG. 9 includes eight light-emitter apparatuses L1-L8. In practice, the LiDAR can include a larger number of light-emitter apparatuses, such as 128, which is not limited in this disclosure. Drive switches G01 and G02 can be provided at cathodes of the light-emitter apparatuses L1-L8. Switch devices T1-T4 can be provided at anodes of the light-emitter apparatuses L1-L8.

In specific implementation, the driver circuit includes a dashed portion 30 except for the light-emitter apparatuses L1-L8. The safety controller unit 322 includes the controller 3222. In the driver circuit, a high-voltage bus HVBUS is used for providing a stable voltage source. After the controller 3222 controls a switch device T1 of the driver circuit to close, the drive switches G01 and G02 are closed in sequence, and light-emitter apparatuses L1 and L5 connected to the switch device T1 are conducted in sequence. Specifically, when the switch device T1 receives the high level, the switch device T1 is closed. Closing time of each GaN is approximately 10 ns. Each switch device is coupled to the controller 3222 through a pulse width changer subunit 3223. The controller 3222 outputs a control pulse signal. The pulse width changer subunit 3223 can control maximum width of the high level in the control pulse signal transmitted to the switch device, to control maximum closing time of each switch device.

In specific implementation, the high-voltage bus HVBUS can specifically include the power supplies VH and VL shown in FIG. 6.

Furthermore, the safety controller unit 322 can further include a filtering subunit 3224. The filtering subunit 3224 is used for filtering out burrs and noise in the control pulse signal. After filtering, transmission speed of the control pulse signal is faster.

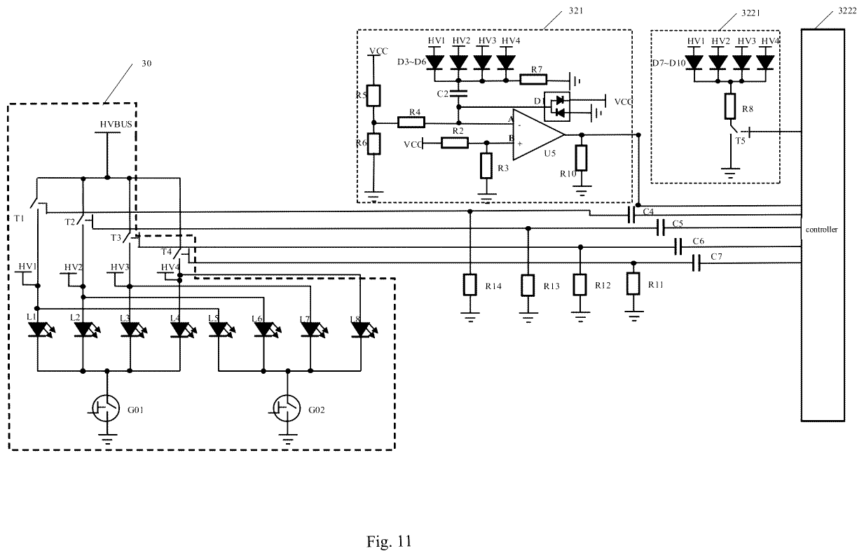

Specifically, with reference to FIG. 10 together, the pulse width changer subunit 3223 includes capacitors C4-C7. The filtering subunit 3224 includes capacitors C4-C7 and resistors R11-R14. The switch device T1 is coupled to the controller 3222 via a capacitor C4 and a resistor R14. One end of the switch device T1 is coupled to the high-voltage bus HVBUS. A control end of the switch device T1 is coupled to one end of the capacitor C4. The other end of the capacitor C4 is coupled to the controller 3222. Similarly, a switch device T2 is coupled to the controller 3222 via a capacitor C5 and a resistor R13. A switch device T3 is coupled to the controller 3222 via a capacitor C6 and a resistor R12. A switch device T4 is coupled to the controller 3222 via a capacitor C7 and a resistor R11. In the case that there is no control signal output from the controller 3222, a low level is output to each switch device. The capacitors C4-C7 play a role of alternating current coupling, transmitting a pulse signal of the controller 3222 and limiting high level width in the control pulse signal. By changing capacitance values of the capacitors C4-C7, a maximum width high level signal of the high level in the control pulse signal transmitted by the controller 3222 to the switch device is limited, thereby limiting the maximum closing time of the switch devices T1-T4.

In this embodiment, four light-emitter apparatuses are grounded through a same drive switch GaN, for example, the light-emitter apparatuses L1-L4 are grounded through a same drive switch G01. The voltage detector unit 321 can detect the voltage of drive voltage HV1-HV4. The eight light-emitter apparatuses in FIG. 9 share the drive voltage HV1-HV4. This means that a voltage detector unit 321 needs to be set in the embodiments of this disclosure. Even if there are more light-emitter apparatuses, such as 64 and 128, as long as all light-emitter apparatuses share the drive voltage HV1-HV4, a voltage detector unit 321 needs to be set in the safety protection circuit in the embodiments of this disclosure, making a circuit structure of the safety protection circuit simple and occupying a small area.

Specifically, with reference to FIG. 7, the voltage detector unit 321 detects voltage values of the drive voltage HV1-HV4 of the light-emitter apparatus. The voltage detector unit 321 includes diodes D3-D6. The diodes D3-D6 are used for preventing crosstalk among multiple drive voltages HV1-HV4. The drive voltage HV1 of the light-emitter apparatus L1 is coupled to the first input end of the first comparator U5 through a diode D3 and the capacitor C2. Similarly, the drive voltage HV2 of the light-emitter apparatus L2 is coupled to the first input end of the first comparator U5 via a diode D4 and the capacitor C2. The drive voltage HV3 of the light-emitter apparatus L3 is coupled to the first input end of the first comparator U5 via a diode D5 and the capacitor C2. The drive voltage HV4 of the light-emitter apparatus L4 is coupled to the first input end of the first comparator U5 via a diode D6 and the capacitor C2.

In this embodiment, the safety controller unit 322 can further includes a discharger subunit 3221. The discharger subunit 3221 discharges the energy storage unit in the driver circuit when the voltage value of the drive voltage is lower than the threshold voltage.

Specifically, with reference to FIG. 8 and FIG. 9 together, the discharger subunit 3221 includes a first load R8 and a first switch T5. The first switch T5 is used for conducting when the voltage value of the drive voltage is lower than the threshold voltage, allowing the energy storage unit (such as a capacitor Cn) to discharge via the first load R8.

In a specific embodiment, with reference to FIG. 9, a control end of the discharger subunit 3221 is coupled to an output end of the voltage detector unit 321, that is, the control end of the discharger subunit 3221 is coupled to the output end of the first comparator U5. A first end of the discharger subunit 3221 is coupled to the energy storage unit, and a second end of the discharger unit 3221 is grounded.

Specifically, the discharger subunit 3221 further includes diodes D7-D10. The diodes D7-D10 are used for preventing the crosstalk among the multiple drive voltage HV1-HV4. The drive voltage HV1 of the light-emitter apparatus L1 is coupled to one end of the switch T5 via a diode D7 and a resistor R8. Similarly, the drive voltage HV2 of the light-emitter apparatus L2 is coupled to one end of the switch T5 via a diode D8 and the resistor R8. The drive voltage HV3 of the light-emitter apparatus L3 is coupled to one end of the switch T5 via the diode D5 and resistor R8. The drive voltage HV4 of the light-emitter apparatus L4 is coupled to one end of the first switch T5 via the diode D6 and the resistor R8. The other end of the switch T5 is grounded.

Furthermore, the discharger subunit 3221 can further include a filtering subunit 32211. The filtering subunit 32211 is used for filtering out burrs and noise in an output signal of the first comparator U5. The filtering subunit 32211 includes a capacitor C3 and a resistor R9. One end of the capacitor C3 is coupled to the output end of the first comparator U5, and the other end of the capacitor C3 is coupled to a control end of the switch T5. One end of the resistor R9 is coupled to the control end of the switch T5, and the other end of the resistor R9 is grounded.

In the embodiments of this disclosure, an output signal of the voltage detector unit 321 directly controls the discharger subunit 3221 to discharge rapidly, so that the light-emitter apparatus stops emitting the light timely, ensuring the human eye safety.

With reference to FIG. 9, and taking the light-emitter apparatus L1 as an example, the controller 3222 outputs a high level signal to control the switch device T1 to close. And the controller 3222 controls closing and opening of a drive switch GaN 01 to control the light-emitter apparatus L1 to emit multiple randomly encoded laser pulse trains, completing normal light emission. In the case that the drive switch GaN 01 fails and cannot be opened, corresponding drive voltage HV1 can drop continuously at this time. The voltage UA at the first input end of the first comparator U5 becomes lower than the voltage UB (i.e., the threshold voltage) at the second input end. The first comparator U5 outputs the high level. At this time, the human eye safety protection mechanism is triggered.

Under the human eye safety protection mechanism, the controller 3222 outputs the low level based on the high level output from the first comparator U5. The switch device T1 is opened to stop supplying the power to the light-emitter apparatus L1. And the high level output from the first comparator U5 can control the switch T5 to close, releasing residual electric charge of the energy storage unit coupled to the drive voltage HV1 through the resistor R8 as soon as possible. The light-emitter apparatus L1 can be ensured to stop emitting the light timely after the switch device T1 is opened. In the embodiments of this disclosure, when the human eye safety protection mechanism is triggered, the first comparator U5 outputs the high level to the controller 3222. The controller 3222 controls whether the human eye safety protection mechanism is triggered by monitoring output of the first comparator U5.

Furthermore, through the controller 3222, a delay control signal can be determined to control the switch devices T1-T4 to open and stop supplying the power to the light-emitter apparatus. During a delay period, the voltage detector unit 321 can repeatedly or continuously identify whether a trigger signal for the human eye safety protection mechanism (i.e., the high level output from the first comparator U5) is received. False triggering of the human eye safety protection mechanism due to noise such as the burrs can be avoided.

Furthermore, when the controller 3222 controls triggering of the human eye safety protection mechanism, it can also output warning information for subsequent maintenance and replacement.

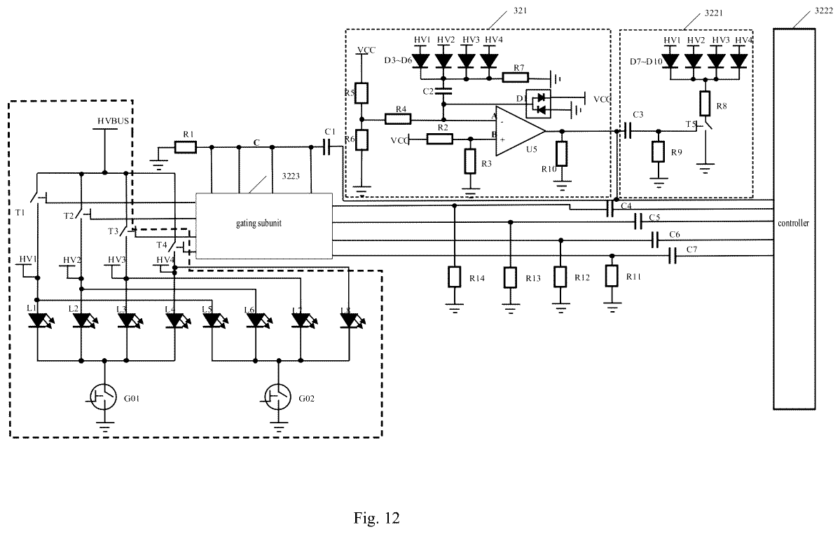

In another specific embodiment, with reference to FIG. 11, an input end of the controller 3222 is coupled to the output end of the voltage detector unit 321. An output end of the controller 3222 is coupled to an input end of the discharger subunit 3221.

Unlike the embodiment corresponding to FIG. 9, where the output signal of the voltage detector unit 321 controls the discharger subunit 3221 to discharge, in this embodiment, the controller 3222 controls the discharger subunit 3221 to discharge.

With reference to FIG. 11, and taking a light-emitter apparatus L1 as an example, the controller 3222 outputs the high level signal to control the switch device T1 to close. And the controller 3222 controls the closing and the opening of the drive switch G01 to control the light-emitter apparatus L1 to emit the multiple randomly encoded laser pulse trains, completing the normal light emission. In the case that the drive switch GaN 01 fails and cannot be opened, the corresponding drive voltage HV1 can drop continuously at this time. The voltage UA at the first input end of the first comparator U5 becomes lower than the voltage UB (i.e., the threshold voltage) at the second input end. The first comparator U5 outputs the high level. At this time, the human eye safety protection mechanism is triggered.

Under the human eye safety protection mechanism, the controller 3222 outputs a low level based on the high level output from the first comparator U5. The switch device T1 can be opened to stop supplying the power to the light-emitter apparatus L1. And when the controller 3222 monitors that the first comparator U5 outputs the high level, the controller 3222 outputs the high level to control the switch T5 to close, releasing residual electric charge of the energy storage unit coupled to the drive voltage HV1 through the resistor R8 as soon as possible. The light-emitter apparatus L1 can be ensured to stop emitting the light timely after the switch device T1 is opened.

With reference to FIG. 12, it shows a specific structure of another safety protection circuit.

Unlike the embodiment corresponding to FIG. 9, the safety controller unit 322 further includes a gating subunit 3223. The gating subunit 3223 is used for outputting a first control signal when the voltage value of the drive voltage is lower than the threshold voltage. The first control signal is used for controlling to stop charging a energy storage unit in the driver circuit. The gating subunit 3223 is used for outputting a second control signal when the voltage value of the drive voltage is higher than the threshold voltage. The second control signal is used for controlling to charge the energy storage unit in the driver circuit. In specific implementation, each gating subunit 3223 corresponds to a switch device in the driver circuit, that is, the number of gating subunits 3223 is the same as the number of switch devices.

Specifically, with reference to FIG. 6 together for illustration, when the first control signal is output by the gating subunit 3223, the first control signal controls a switch device Tn to connect to the power supply VL, that is, the capacitor Cn is grounded via the switch device Tn, and the capacitor Cn stops charging. When the gating subunit 3223 outputs the second control signal, the second control signal controls the switch device Tn to connect to the power supply VH, that is, the capacitor Cn is connected to the power supply VH via the switch Tn, and the capacitor Cn charges.

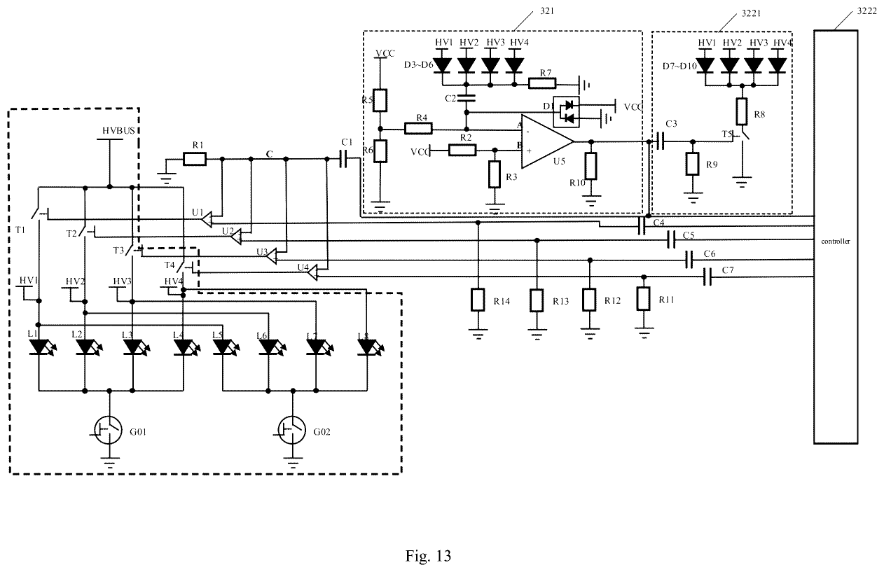

With reference to FIG. 13 for details, the gating subunit 3223 includes comparators U1-U4. An output end of a comparator U1 is coupled to the control end of the switch device T1. An output end of a comparator U2 is coupled to a control end of a switch device T2. An output end of a comparator U3 is coupled to a control end of a switch device T3. An output end of a comparator U4 is coupled to a control end of a switch device T4. First input ends of the comparators U1-U4 are coupled to the output end of the voltage detector unit 321. A second input end of the comparator U1 is connected to a control signal of the switch device T1 from the controller 3222. A second input end of the comparator U2 is connected to a control signal of the switch device T2 from the controller 3222. A second input end of the comparator U3 is connected to a control signal of the switch device T3 from the controller 3222. A second input end of the comparator U4 is connected to a control signal of the switch device T4 from the controller 3222.

In a specific embodiment, second input ends of the comparators U1-U4 can be directly coupled to the output end of the controller 3222.

In another specific embodiment, the second input end of the comparator U1 is coupled to one end of the capacitor C4. The second input end of the comparator U2 is coupled to one end of the capacitor C5. The second input end of the comparator U3 is coupled to one end of the capacitor C6. Tnd the second input end of the comparator U4 is coupled to one end of the capacitor C7. For more connection methods of the capacitors C4-C7 and the resistors R11-R14, refer to the embodiment corresponding to FIG. 9, which is not repeated herein.

In a non-limiting embodiment, the first input ends of the comparators U1-U4 can be directly coupled to the output end of the voltage detector unit 321. Alternatively, the first input ends of the comparators U1-U4 are coupled to the output end of the voltage detector unit 321 via the capacitor C1, and the first input ends of the comparators U1-U4 are grounded via the resistor R1. The resistor R1 is a pull-down resistor. When the human eye safety protection mechanism is not triggered, the first input ends of the comparators U1-U4 are always at low level to ensure that the controller 3222 can control normal closing and opening of the switch devices T1-T4 normally.

In the embodiments of this disclosure, taking the light-emitter apparatus L1 as an example, the controller 3222 outputs the high level signal to a positive phase input end of the comparator U1. Since the drive voltage UA (input voltage of a negative phase input end) of the first comparator U5 is greater than the threshold voltage UB (input voltage of a positive phase input end), and the first comparator U5 outputs the low level to the negative phase input end of the comparator U1, the comparator U1 outputs the high level, controlling the switch device T1 to close. And the controller 3222 controls the closing and the opening of the G01 to control the light-emitter apparatus L1 to emit the multiple randomly encoded laser pulse trains, completing the normal light emission.

In the case that the G01 fails and cannot be opened, the drive voltage HV1 of the light-emitter apparatus L1 can drop continuously at this time, causing that input voltage UA of the negative phase input end of the first comparator U5 is lower than input voltage UB of the positive phase input end. The first comparator U5 outputs the high level, and a voltage of the high level is higher than a voltage output from the controller 3222 to the positive phase input end of the comparator U1. The comparator U1 outputs a low level to control the switch device T1 to open and the light-emitter apparatus L1 to stops emitting the light. And since the first comparator U5 outputs the high level, the switch T5 is closed. The residual electric charge of the energy storage unit coupled to the drive voltage HV1 is released as soon as possible through the resistor R8. The light-emitter apparatus L1 can be ensured to stop emitting the light timely after the switch device T1 is opened.

In addition, the output signal of the voltage detector unit 321 is used for controlling the switch devices T1-T4 to open to stop supplying the power through, and directly controlling the discharger subunit 3221 to discharge rapidly. The human eye safety protection mechanism is triggered without delay, with fast response speed, further making the light-emitter apparatus stop emitting the light timely, ensuring the human eye safety.

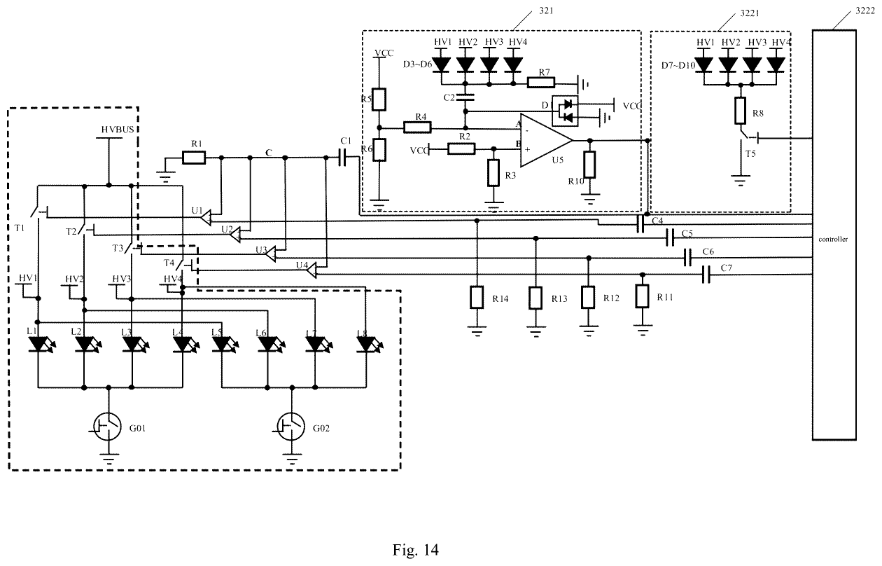

With reference to FIG. 14, it shows a specific structure of yet another safety protection circuit.

Unlike the embodiment corresponding to FIG. 13, where the output signal of the voltage detector unit 321 controls the discharger subunit 3221 to discharge, in this embodiment, the controller 3222 controls the discharger subunit 3221 to discharge.

With reference to FIG. 14 y, and taking the light-emitter apparatus L1 as an example, the controller 3222 outputs the high level signal to the positive phase input end of the comparator U1. Since the drive voltage UA (the input voltage of the negative phase input end) of the first comparator U5 is greater than the threshold voltage UB (the input voltage of the positive phase input end), and the first comparator U5 outputs the low level to the negative phase input end of the comparator U1, the comparator U1 outputs the high level, controlling the switch device T1 to close. And the controller 3222 controls the closing and the opening of the G01 to control the light-emitter apparatus L1 to emit the multiple randomly encoded laser pulse trains, completing the normal light emission.

In the case that the G01 fails and cannot be opened, the drive voltage HV1 of the light-emitter apparatus L1 can drop continuously at this time, causing that the input voltage UA of the negative phase input end of the first comparator U5 is lower than the input voltage UB of the positive phase input end. The first comparator U5 outputs the high level. A voltage of the high level is higher than a voltage output from the controller 3222 to the positive phase input end of the comparator U1. The comparator U1 outputs a low level. The switch device T1 is controlled to open and the light-emitter apparatus L1 is controlled to stop emitting the light. And when the controller 3222 monitors that the first comparator U5 outputs the high level, the controller 3222 outputs the high level to control the switch T5 to close, releasing the residual electric charge of the energy storage unit coupled to the drive voltage HV1 through the resistor R8 as soon as possible. The light-emitter apparatus L1 can be ensured to stop emitting the light timely after the switch device T1 is opened.

For more specific embodiments of the safety protection circuit shown in FIG. 14, refer to the relevant description of embodiments corresponding to FIG. 8 and FIG. 9, which is not repeated herein.

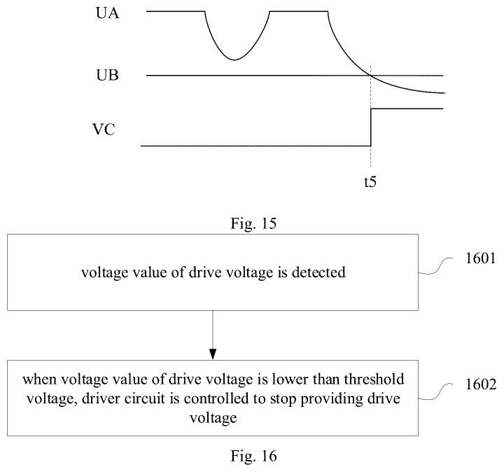

In a specific application scenario, with reference to FIG. 12 and FIG. 15 together, or FIG. 14 and FIG. 15, before time point t5, the drive voltage UA (the input voltage of the negative phase input end) of the first comparator U5 is greater than the threshold voltage UB (the input voltage of the positive phase input end). Output voltage VC of the first comparator U5 is at a low level. After the time point t5, the drive voltage UA of the first comparator U5 is less than the threshold voltage UB, which represents that the drive switch GaN fails. The output voltage VC of the first comparator U5 is at a high level. That the output voltage VC is at a high level is the trigger signal for the human eye protection safety mechanism.

With reference to FIG. 16, the embodiments of this disclosure further disclose a drive detection method for a LiDAR. The drive detection method can specifically include the following steps.

At step 1601, a voltage value of a drive voltage is detected.

At step 1602, when the voltage value of the drive voltage is lower than a threshold voltage, a driver circuit is controlled to stop providing the drive voltage.

It can be understood that in specific implementation, the drive detection method can be implemented in a form of a software program, which runs in a processor integrated inside a chip or a chip module. The method can also be implemented in a combined manner of software and hardware, which is not limited in this disclosure.

In specific implementation of the step 1601, it is not necessary to detect a specific voltage value of the drive voltage, instead, a comparison result between the voltage value of the drive voltage and the threshold voltage can be detected.

In specific implementation of the step 1602, controlling the driver circuit to stop providing the drive voltage can specifically be controlling a charger unit in the driver circuit to stop charging an energy storage unit and controlling the energy storage unit to discharge.

For more specific implementation manners of the drive detection method, refer to the aforesaid embodiments, which is not repeated herein.

The embodiments of this disclosure further disclose a LiDAR. The LiDAR includes at least one light-emitter apparatus. The LiDAR emits detection beams through multiple light-emitter apparatuses. The LiDAR further includes the safety protection circuit in any of the aforementioned embodiments. The LiDAR can control the light-emitter apparatus to emit the light or to stop emitting the light while ensuring the human eye safety through the safety protection circuit.

Further, the LiDAR further includes multiple light-receiver apparatuses. The multiple light-receiver apparatuses are used for receiving echo beams of the detection beams reflected by obstacles. The multiple light-receiver apparatuses are arranged in correspondence with the multiple light-emitter apparatuses, respectively.

It should be understood that the term “and/or” in this disclosure is merely an association relationship describing related objects, which means that there can be three relationships, for example, A and/or B can represent three situations: A exists alone, A and B exist at the same time, and B exists alone. In addition, the character “/” in this disclosure represents that the related objects are in an “or” relationship.

“Multiple” described in the embodiments of this disclosure means two or more.

The “first,” “second,” or the like described in the embodiments of this disclosure are merely for the purpose of illustrating and distinguishing objects described, and are not in any order, nor do they represent any special limitation on the number of devices in the embodiments of this disclosure, and cannot constitute any limitation on the embodiments of this disclosure.

The “connection” in the embodiments of this disclosure includes various connection modes, such as direct connection and indirect connection, to realize a communication between devices, and the embodiments of this disclosure do not make any limitation.

The above embodiments can be fully or partially implemented by software, hardware, firmware, or any other combinations. When the software is used for implementation, the above embodiments can be fully or partially implemented in the form of a computer program product. The computer program product includes one or more computer instructions or computer programs. When the computer instruction or computer program is loaded or executed on a computer, processes or functions based on the embodiments of this disclosure are fully or partially generated. The computer can be a general computer, a special computer, a computer network, or other programmable apparatus. The computer instruction can be stored in a computer-readable storage medium or transmitted from one computer-readable storage medium to another computer-readable storage medium. For example, the computer instruction can be transmitted from a website site, computer, server, or data center to another website site, computer, server, or data center in a wired or wireless manner. The computer-readable storage medium can be any available medium that can be accessed by a computer, or a data storage device such as a server or data center that includes one or more available mediums integrated.

In several embodiments provided in this disclosure, it should be understood that the disclosed method, apparatus, and system can be implemented in other manners. For example, an apparatus embodiment described above is merely schematic; for example, division of the units is merely logic function division, and other division manners can be adopted during practical implementation; and for example, multiple units or components can be combined or integrated into another system, or some characteristics can be neglected or not executed. In addition, the displayed or discussed mutual coupling or direct coupling or communication connection can be indirect coupling or communication connection through some interfaces, devices, or units, and can be in electrical, mechanical, or other forms.

The units described as separate components can or can not be physically separated. The components displayed as units can or can not be physical units, that is, the components can be located in one place, or can also be arranged on multiple network units. Some or all of the units can be selected based on actual needs to achieve the purposes of the solutions of these embodiments.

In addition, the functional units in the various embodiments of this disclosure can be integrated into one processor unit, or each unit can exist alone physically, or two or more units can be integrated into one unit. The above integrated unit can be implemented in a hardware form, or can also be implemented in the form of hardware and software functional units.

The integrated unit implemented in the form of a software functional unit described above can be stored in a computer-readable storage medium. The software functional unit is stored in a storage medium, and includes multiple instructions configured to cause a computer device (which can be a personal computer, a server, a network device, or the like) to execute some of the steps of the method described in various embodiments of this disclosure.

Although this disclosure is disclosed as above, this disclosure is not limited thereto. Any person skilled in the art can make various changes and modifications without departing from the spirit and scope of this disclosure. In such a case, the protection scope of this disclosure should be subject to the scope defined by the claims.

1. A safety protection circuit for a driver circuit of a LiDAR, wherein the LiDAR comprises a light-emitter apparatus, the driver circuit provides a drive voltage to drive the light-emitter apparatus to emit light, one end of the light-emitter apparatus receives the drive voltage, and the other end of the light-emitter apparatus is coupled to a drive switch; and
wherein the safety protection circuit comprises:
a voltage detector unit configured to detect a voltage value of the drive voltage; and
a safety controller unit configured to control the driver circuit to stop providing the drive voltage when a voltage value of the drive voltage is lower than a threshold voltage, wherein the threshold voltage represents a voltage value of the drive voltage when the drive switch fails.

2. The safety protection circuit of claim 1, wherein when the light-emitter apparatus emits the light normally, the drive voltage has a maximum voltage value and a minimum voltage value during a voltage repetition period, and the threshold voltage is less than the minimum voltage value.

3. The safety protection circuit of claim 2, wherein a difference value between the maximum voltage value and the minimum voltage value is a first voltage variation, the threshold voltage is a difference value between the minimum voltage value and a safety voltage variation, and the safety voltage variation is a product of the first voltage variation and a preset ratio.

4. The safety protection circuit of claim 2, wherein the threshold voltage is less than the minimum voltage value and greater than a safety allowable voltage value, and the safety allowable voltage value is a voltage value of the drive voltage when light-emitting duration of the light-emitter apparatus reaches a safety light-emitting time threshold.

5. The safety protection circuit of claim 4, wherein the threshold voltage is an intermediate value between the minimum voltage value and the safety allowable voltage value.

6. The safety protection circuit of claim 1, wherein the driver circuit comprises a charger unit and an energy storage unit, wherein the charger unit is configured to charge the energy storage unit, and the energy storage unit provides the drive voltage; and
when the voltage value of the drive voltage is lower than the threshold voltage, the safety controller unit controls the charger unit to stop charging the energy storage unit and controls the energy storage unit to discharge.

7. The safety protection circuit of claim 1, wherein the voltage detector unit comprises:
a comparison subunit configured to output a first voltage of a comparison result between the drive voltage and the threshold voltage, wherein the first voltage represents whether the drive voltage is abnormal.

8. The safety protection circuit of claim 7, wherein the comparison subunit comprises:
a first comparator, wherein a positive input end of the first comparator is connected to the threshold voltage, a negative input end of the first comparator is connected to the drive voltage, and an output end of the first comparator outputs the first voltage.

9. (canceled)

10. (canceled)

11. The safety protection circuit of claim 1, wherein the other end of N light-emitter apparatuses is coupled to a same drive switch, the number of the drive switches is M, the number of the light-emitter apparatuses of the LiDAR is N×M, and N and M are positive integers greater than 1; and
the voltage detector unit is configured to detect a voltage value of the drive voltage driving the N light-emitter apparatuses.

12. The safety protection circuit of claim 11, wherein each light-emitter apparatus is connected to a power supply via a switch device, a first end of the switch device is coupled to the power supply, a second end of the switch device is coupled to the one end of the light-emitter apparatus, and each input end of the voltage detector unit is coupled to a second end of the switch device, respectively.

13. The safety protection circuit of claim 1, wherein the safety controller unit comprises:
a discharger subunit configured to discharge an energy storage unit in the driver circuit when the voltage value of the drive voltage is lower than the threshold voltage.

14. The safety protection circuit of claim 13, wherein a control end of the discharger subunit is coupled to an output end of the voltage detector unit, a first end of the discharger subunit is coupled to the energy storage unit, and a second end of the discharger subunit is grounded.

15. The safety protection circuit of claim 13, wherein the safety controller unit comprises:
a controller, wherein an input end of the controller is coupled to an output end of the voltage detector unit, and an output end of the controller is coupled to an input end of the discharger subunit.

16. (canceled)

17. The safety protection circuit of claim 15, wherein the controller controls to stop charging the energy storage unit in the driver circuit when the voltage value of the drive voltage is lower than the threshold voltage.

18. The safety protection circuit of claim 13, wherein the discharger subunit comprises:
a first load; and
a first switch configured to conduct when the voltage value of the drive voltage is lower than the threshold voltage, allowing the energy storage unit to discharge via the first load.

19. The safety protection circuit of claim 1, wherein the safety controller unit comprises:
a gating subunit configured to output a first control signal when the voltage value of the drive voltage is lower than the threshold voltage, wherein the first control signal is configured to control to stop charging the energy storage unit in the driver circuit; and
the gating subunit configured to output a second control signal when the voltage value of the drive voltage is higher than the threshold voltage, wherein the second control signal is configured to control to charge the energy storage unit in the driver circuit.

20. The safety protection circuit of claim 19, wherein an input end of the gating subunit is coupled to an output end of the voltage detector unit.

21. (canceled)

22. (canceled)

23. A drive detection method for a LiDAR, wherein the LiDAR comprises a light-emitter apparatus, a driver circuit provides a drive voltage to drive the light-emitter apparatus, and one end of the light-emitter apparatus receives the drive voltage, and the other end of the light-emitter apparatus is coupled to a drive switch; wherein the drive detection method comprises:
detecting a voltage value of the drive voltage; and
when a voltage value of the drive voltage is lower than a threshold voltage, controlling the driver circuit to stop providing the drive voltage, wherein the threshold voltage represents a voltage value of the drive voltage when the drive switch fails.

24. The drive detection method of claim 23, wherein the driver circuit comprises a charger unit and an energy storage unit, wherein the charger unit is configured to charge the energy storage unit, and the energy storage unit provides the drive voltage; and the controlling the driver circuit to stop providing the drive voltage comprises:
controlling the charger unit to stop charging the energy storage unit, and
controlling the energy storage unit to discharge.

25. A LiDAR, comprising:
a light-emitter apparatus;
a driver circuit configured to provide a drive voltage to drive the light-emitter apparatus to emit light, one end of the light-emitter apparatus receiving the drive voltage, and the other end of the light-emitter apparatus being coupled to a drive switch; and
a safety protection circuit for the driver circuit; and
wherein the safety protection circuit comprises:
a voltage detector unit configured to detect a voltage value of the drive voltage; and
a safety controller unit configured to control the driver circuit to stop providing the drive voltage when a voltage value of the drive voltage is lower than a threshold voltage, wherein the threshold voltage represents a voltage value of the drive voltage when the drive switch fails.
